(19) United States
(12) Patent Application Publication
(10) Pub. No.: US 2010/0193792 A1
(43) Pub. Date: Aug. 5, 2010

(54) LAMINATED FILM MANUFACTURING METHOD, SEMICONDUCTOR DEVICE MANUFACTURING METHOD, SEMICONDUCTOR DEVICE AND DISPLAY DEVICE

(76) Inventor: Toshiaki Miyajima, Osaka (JP)

Correspondence Address: BIRCH STEWART KOLASCH & BIRCH, PO BOX 747, FALLS CHURCH, VA, 22040-0747, US

(21) Appl. No.: 12/669,762

(22) PCT Filed: Jul. 14, 2008
(86) PCT No.: PCT/JP2008/001888

§ 371 Date: Jan. 19, 2010

(30) Foreign Application Priority Data
Jul. 20, 2007 (JP) 2007-189127

(51) Int. Cl. H01L 33/16; H01L 21/20; H01L 29/786

(52) U.S. Cl. 257/59; 438/487; 257/57; 257/E21.134; 257/E29.289; 257/E33.004

(57) ABSTRACT

A production method for a semiconductor film according to the present invention includes: step (a) of forming a first film 103 supported by a substrate 101; step (b) of forming a second film 102 being supported by the substrate and having a lower thermal conductivity than that of the first film 103; step (c) of depositing a semiconductor film 104 in an amorphous state above the first film 103 and the second film 102; and step (d) of irradiating portions of the semiconductor film 104 that are located above the first film 103 and the second film 102 with an energy beam of the same intensity, thereby crystallize the portion of the semiconductor film 104 that is located above the second film 102 and leaving the portion of the semiconductor film 104 that is located above the first film 103 in the amorphous state.

### TECHNICAL FIELD

The present invention relates to a production method for a multilayer film having a crystalline semiconductor layer and an amorphous semiconductor layer, a production method for a semiconductor device, and a semiconductor device and a display device.

### BACKGROUND ART

As a thin film transistor (hereinafter referred to as “a TFT”) of a liquid crystal display device, a thin film transistor in which a polycrystalline silicon layer formed on a substrate functions as an active region is conventionally known. This polycrystalline silicon layer is formed by irradiating an amorphous silicon film which is formed on a substrate with an energy beam to crystallize the amorphous silicon film. A polycrystalline silicon film exhibits different electrical characteristics depending on its average grain size.

Generally speaking, a polycrystalline silicon film has a nature such that: the smaller the average grain size of the polycrystalline silicon film is, the less likely a leak current in the TFT is to occur; and the greater the average grain size is, the greater the carrier mobility is. Therefore, by using a region with a small average grain size, it is possible to realize a transistor having a small leak current, and by forming a transistor by using a region with a large average grain size, an improvement in carrier mobility can be realized.

Patent Document 1 discloses a method of forming polycrystalline silicon films with different average grain sizes by radiating laser light of the same intensity onto an amorphous silicon film that is formed on an underlayer film having varying film thicknesses. According to Patent Document 1, the cooling rate when performing a laser annealing differs between portions of an amorphous silicon film that are associated with different thicknesses of its underlayer film, such that a polycrystalline silicon film having a smaller average grain size is formed in a region having a larger cooling rate, and a polycrystalline silicon film having a larger average grain size is formed in a region having a smaller cooling rate.

On the other hand, Patent Document 2 discloses a liquid crystal device in which a static random access memory (SRAM) is provided for each pixel as a means of retaining gray scale data. In this liquid crystal device, for each pixel, a TFT for applying a voltage across liquid crystal and a TFT for composing an SRAM circuit are formed. Generally speaking, characteristics with little leak current are required of a TFT for applying a voltage across liquid crystal, whereas a high carrier mobility is required of a TFT constituting an SRAM circuit.

[Patent Document 1] Japanese Laid-Open Patent Publication No. 11-95259

[Patent Document 2] Japanese Laid-Open Patent Publication No. 11-295700

### DISCLOSURE OF INVENTION

### Problems to be Solved by the Invention

The method disclosed in Patent Document 1 has a problem in that, even if TFTs having polycrystalline silicon layers with different average grain sizes are formed, characteristics which are required for each TFT cannot be sufficiently obtained. For example, even if a TFT is formed by using a region with a small average grain size, the leak current cannot be said to be sufficiently small, and a further reduction in leak current is being required.

Moreover, in order to realize the structure which is disclosed in Patent Document 2, the TFT which is required to have characteristics with little leak current and the TFT which is required to have a high carrier mobility need to be formed in regions close to each other. However, it is difficult to irradiate regions which are close to each other with laser light of different intensities.

The present invention has been made in view of the above problems, and an objective thereof is to provide a method which allows an amorphous semiconductor layer and a crystalline semiconductor layer to be formed with a free layout, and by producing TFTs by using an amorphous semiconductor layer and a crystalline semiconductor layer, provide a semiconductor device in which a TFT having little leak current and a TFT having a high carrier mobility are disposed with a free layout, as well as a display device including the same.

Furthermore, an objective of the present invention is to provide a method which allows an amorphous semiconductor layer and a crystalline semiconductor layer to be formed in close proximity to each other, and by producing TFTs by using an amorphous semiconductor layer and a crystalline semiconductor layer, provide a semiconductor device in which a TFT having little leak current and a TFT having a high carrier mobility are disposed in regions close to each other, as well as a display device including the same.

### Means for Solving the Problems

A production method for a multilayer film according to the present invention comprises: step (a) of forming a first film supported by a substrate; step (b) of forming a second film being supported by the substrate and having a lower thermal conductivity than that of the first film; step (c) of depositing a semiconductor film in an amorphous state above the first film and the second film; and step (d) of irradiating portions of the semiconductor film that are located above the first film and the second film with an energy beam of a same intensity, thereby crystallizing the portion of the semiconductor film that is located above the second film and leaving the portion of the semiconductor film that is located above the first film in the amorphous state.

In one embodiment, in step (c), the semiconductor film is formed so as to be in direct contact with the first film and the second film.

One embodiment further comprises, after step (b) and before step (c), a step of forming a third film which is in direct contact with the first film and the second film, wherein, in step (c), the semiconductor film is formed on the third film.

In one embodiment, the first film is an insulating film.

In one embodiment, the first film is an electrically conductive film.

In one embodiment, the energy beam is light.

In one embodiment, the light is laser light.

In one embodiment, the semiconductor film contains at least one of silicon and germanium.

A production method for a semiconductor device according to the present invention comprises: step (a) of forming a first film supported by a substrate; step (b) of forming a second film being supported by the substrate and having a lower thermal conductivity than that of the first film; step (c) of depositing a semiconductor film in an amorphous state above the first film and the second film; and step (d) of irradiating portions of the semiconductor film that are located above the first film and the second film with an energy beam of a same intensity, thereby crystallizing the portion of the semiconductor film that is located above the second film to form a crystalline semiconductor film and leaving the portion of the semiconductor film that is located above the first film in the amorphous state to become an amorphous semiconductor film.

One embodiment further comprises, after step (d), step (e) of performing a patterning to form an island-shaped crystalline semiconductor layer which at least includes a portion of the crystalline semiconductor film and an island-shaped amorphous semiconductor layer which at least includes a portion of the amorphous semiconductor film, and step (f) of forming thin film transistors by respectively using the island-shaped crystalline semiconductor layer and the island-shaped amorphous semiconductor layer.

A semiconductor device according to the present invention is a semiconductor device having a first thin film transistor and a second thin film transistor, comprising: a substrate; a first film supported by the substrate; a second film being supported by the substrate and having a lower thermal conductivity than that of the first film; an amorphous semiconductor layer formed above the first film, the amorphous semiconductor layer composing the first thin film transistor; and a crystalline semiconductor layer formed above the second film, the crystalline semiconductor layer composing the second thin film transistor.

In one embodiment, the first thin film transistor and the second thin film transistor are provided for each pixel.

In one embodiment, the first thin film transistor is provided for each pixel, and the second thin film transistor is provided outside the pixels.

In one embodiment, the amorphous semiconductor layer is in direct contact with the first film; and the crystalline semiconductor layer is in direct contact with the second film.

In one embodiment, a third film is formed on the first film and the second film; and the amorphous semiconductor layer and the crystalline semiconductor layer are formed on the third film.

In one embodiment, the first film is an electrode which is connected to an arbitrary potential, including a ground potential.

In one embodiment, the first film is an electrode for controlling a threshold value voltage of the thin film transistor.

In one embodiment, the first film is a gate electrode of the first thin film transistor.

In one embodiment, the substrate is made of a material which transmits visible light.

In one embodiment, the first film is made of a material which blocks visible light.

A display device according to the present invention comprises a semiconductor device according to the present invention.

### EFFECTS OF THE INVENTION

According to the present invention, a crystalline semiconductor layer and an amorphous semiconductor layer can be freely disposed, including close regions. Therefore, a TFT which is required to have high carrier-mobility characteristics can be formed by using the crystalline semiconductor layer, and a TFT having little leak current can be formed by using the amorphous semiconductor layer.

### BRIEF DESCRIPTION OF DRAWINGS

FIG. 1 (a) to (c) are schematic diagrams showing production steps of a multilayer film according to an embodiment of the present invention.

FIGS. 2 (a) and (b) are schematic diagrams showing variations of the multilayer film according to an embodiment of the present invention.

FIG. 3 (a) to (f) are schematic diagrams showing production steps of a multilayer film of Embodiment 1.

FIG. 4 (a) to (f) are schematic diagrams showing production steps of a multilayer film of Embodiment 2.

FIG. 5 (a) to (c) are schematic diagrams showing production steps of a semiconductor device of Embodiment 3.

FIG. 6 A schematic diagram showing a semiconductor device of Embodiment 4.

FIG. 7 A schematic diagram showing a semiconductor device of Embodiment 5.

FIG. 8 (a) is a schematic diagram showing the structure of a TFT substrate in a liquid crystal display device of Embodiment 6; and (b) is a schematic diagram showing the structure of a CF substrate in the liquid crystal display device of Embodiment 6.

### DESCRIPTION OF REFERENCE NUMERALS

1 glass substrate
2 silicon oxide film
3 silicon nitride film
4 amorphous silicon film
5 pulsed excimer laser light
6 amorphous silicon film
7 crystalline silicon film
8 W film
9 silicon oxide film
10 amorphous silicon layer
11 crystalline silicon layer
12 silicon oxide film
13 W film
14 silicon oxide film
15 Al wiring
16 silicon nitride film
17 resin film
18 ITO film
19 polyimide film
20 glass substrate
21 color filter
22 ITO film
23 polyimide film
30, 31 recess
32, 33, 35, 36, 37, 38 TFT
34, 39, 40 contact hole
101 substrate
102 second film
103 first film
104 semiconductor film
105 energy beam
106 amorphous semiconductor layer
107 crystalline semiconductor layer
109 third film

### BEST MODE FOR CARRYING OUT THE INVENTION

Hereinafter, with reference to the drawings, preferable embodiments of the present invention will be described in detail. Note that, the present invention is not limited to the embodiments.

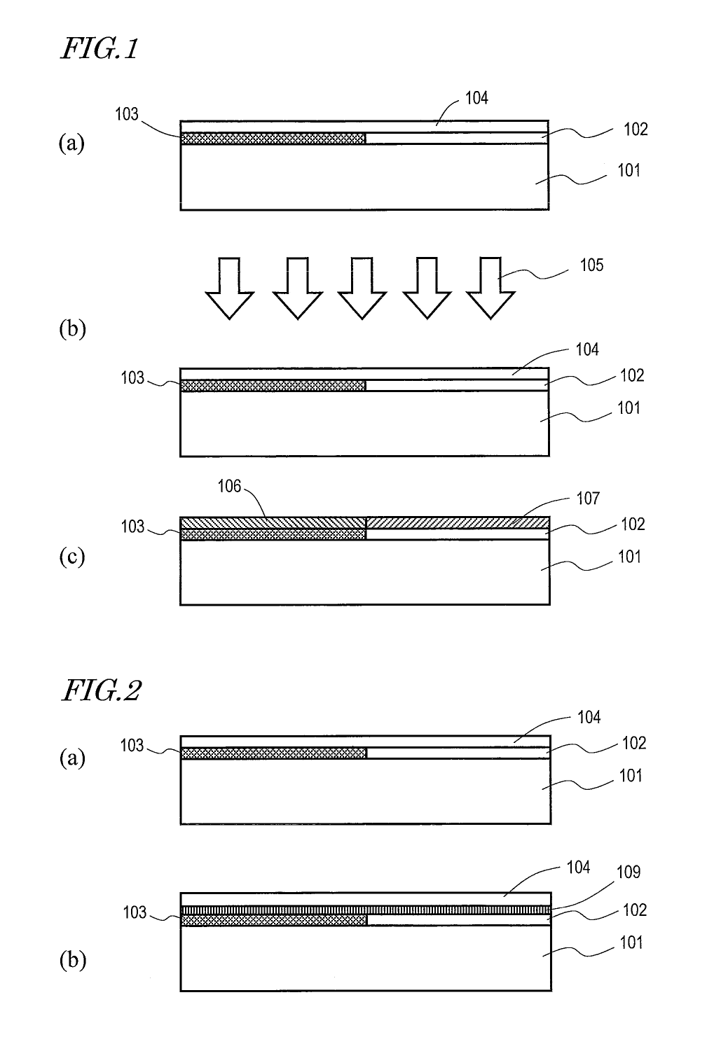

First, with reference to FIGS. 1(a) to (c), a production method for a multilayer film according to an embodiment of the present invention will be described.

The production method for a multilayer film according to an embodiment of the present invention includes: a step of forming a first film 103 which is supported by a substrate 101; a step of forming a second film 102 which is supported by the substrate 101 and which has a lower thermal conductivity than that of the first film 103; and a step of depositing above the first film 103 and the second film 102 a semiconductor film 104 which is in an amorphous state. By performing these steps, a structure as shown in FIG. 1(a) is obtained. Next, as shown in FIG. 1(b), portions of the semiconductor film 104 that are located above the first film 103 and the second film 102 are irradiated with an energy beam 105 of the same intensity.

At this point, the semiconductor film 104 is heated because of absorbing the energy beam 105, and a portion of the heat is released to the exterior. Since the first film 103 and the second film 102 are disposed below the semiconductor film 104, and the first film 103 has a higher thermal conductivity than that of the second film 102, more heat is released in the first film 103 than in the second film 102. Therefore, more heat is stored in the portion of the semiconductor film 104 that is located above the second film 102 than in the portion of the semiconductor film 104 that is located above the first film 103. In other words, the temperature of the portion of the semiconductor film 104 that is located above the second film 102 becomes higher than the temperature of the portion of the semiconductor film 104 that is located above the first film 103.

When the temperature of the semiconductor film 104 exceeds a certain value due to irradiation of pulsed excimer laser light, crystallization occurs during the process in which the semiconductor film 104 in an amorphous state melts and thereafter solidifies. In the present embodiment, the temperature of the portion of the semiconductor film 104 that is located above the second film 102 is set so as to exceed the aforementioned value, and the temperature of the portion of the semiconductor film 104 that is located above the first film 103 is set so as not to exceed the aforementioned value. Since the temperature of the semiconductor film 104 will differ depending on the material and film thickness of the semiconductor film 104 or the intensity and the like of the pulsed excimer laser, these values are adjusted in the present embodiment.

As a result of irradiating the semiconductor film 104 with pulsed excimer laser light, as shown in FIG. 1(c), the portion of the semiconductor film 104 that is located above the second film 102 is crystallized to form a crystalline semiconductor layer 107, whereas the portion of the semiconductor film 104 that is located above the first film 103 is left in an amorphous state to become an amorphous semiconductor layer 106.

In the present embodiment, for example, a silicon oxide film is used as the second film 102, and a silicon nitride film or a W film is used as the first film 103.

In the technique described in Patent Document 1, after an amorphous silicon film is melted through laser light irradiation, polycrystalline silicon films of different average grain sizes are formed by utilizing a difference in cooling rate during the solidification process. In contrast, the present embodiment utilizes a greater difference in thermal conductivity of the underlayer so that only a partial region of the region that is irradiated with laser light is melted and crystallized, whereas the other regions maintain an amorphous state. In Patent Document 1, an SiO₂ film having film thicknesses of 2000 angstroms and 6000 angstroms is used as an undercoat, so that the cooling rate can only have a triple difference at the most (as compared in film thickness). On the other hand, there is a difference by one digit or more between the thermal conductivities of a silicon oxide film and a silicon nitride film, or the thermal conductivities of a silicon oxide film and a W film, that are used in the present embodiment. Therefore, the underlayer in the present embodiment has a difference in cooling rate which is greater than that of Patent Document 1. The crystalline semiconductor layer 107 and the amorphous semiconductor layer 106 can be formed by forming the amorphous-state semiconductor film 104 on such an underlayer and thereafter performing a heat treatment.

With this method, the layout of the crystalline semiconductor layer 107 and the amorphous semiconductor layer 106 can be determined based on the layout of the first film 103 and the second film 102, so that the crystalline semiconductor layer 107 and the amorphous semiconductor layer 106 can be freely disposed in regions close to each other.

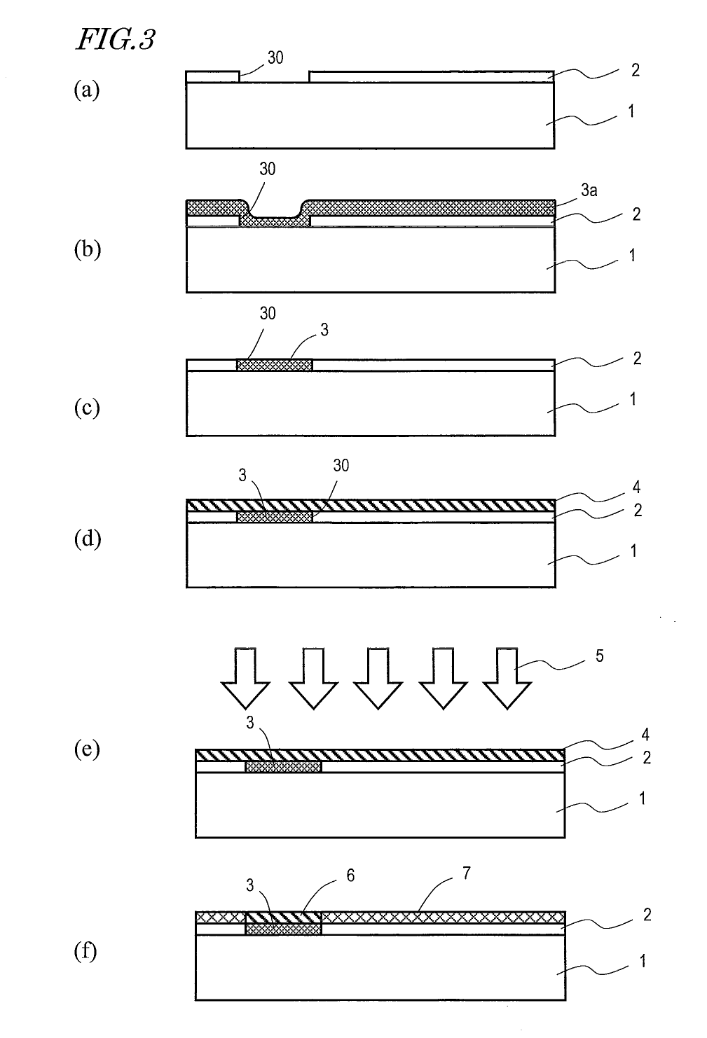

In the present embodiment, as shown in FIG. 2(a), the semiconductor film 104 may be formed so as to be in direct contact with the first film 103 and the second film 102. In this case, the difference in thermal conductivity between the first film 103 and the second film 102 directly affects the thermal emission rate of the semiconductor film 104, thus providing an advantage in that the crystalline semiconductor layer 107 and the amorphous semiconductor layer 106 are easy to produce.

However, in the present embodiment, the first film 103 and the second film 102 do not need to be in contact with the semiconductor film 104. Specifically, as shown in FIG. 2(b), before forming the semiconductor film 104, a step of forming a third film 109 which is in direct contact with the first film 103 and the second film 102 may be further included, thereby forming the semiconductor film 104 on the third film 109.

Next, Embodiment 1 to Embodiment 6 will be described as more specific embodiments of the present invention.

### Embodiment 1

First, a multilayer film of Embodiment 1 will be described with reference to FIG. 3(f). FIGS. 3(a) to (f) are schematic diagrams showing steps of producing the multilayer film of Embodiment 1, where FIG. 3(f) shows a completed state of the multilayer film of Embodiment 1.

As shown in FIG. 3(f), the multilayer film of the present embodiment includes: a glass substrate 1; a silicon oxide film 2 formed on the glass substrate 1; a silicon nitride film 3 being formed on the glass substrate 1 and having a higher thermal conductivity than that of the silicon oxide film 2; a crystalline silicon film 7 formed on the silicon oxide film 2; and an amorphous silicon film 6 formed on the silicon nitride film 3.

Next, the production method for the multilayer film of Embodiment 1 will be described with reference to FIGS. 3(a) to (f).

In the production method for the multilayer film of the present embodiment, as shown in FIG. 3(a), first, a plasma CVD (chemical vapor deposition) technique is performed by using TEOS (tetraethoxysilane) gas and O₃ gas, thereby forming on the glass substrate 1 the silicon oxide film 2 having a thickness of 400 nm. Herein, the silicon oxide film 2 does not need to be in contact with the glass substrate 1, but only needs to be supported by the glass substrate 1. Specifically, an insulative film or the like may be present between the glass substrate 1 and the silicon oxide film 2.

Thereafter, an RIE (reactive ion etching) technique is performed by using CF₄ gas and CHF₃ gas to remove a portion of the silicon oxide film 2 until the surface of the glass substrate 1 is exposed, thereby forming a recess 30.

Next, as shown in FIG. 3(b), a plasma CVD technique is performed by using SiH₄ gas, NH₃ gas, and N₂ gas, thereby forming a silicon nitride film 3a having a thickness of 400 nm. The silicon nitride film 3a covers the silicon oxide film 2 and the surface of the glass substrate 1 exposed in the recess 30.

Thereafter, as shown in FIG. 3(c), an RIE technique is performed by using CF₄ gas and CHF₃ gas to remove a portion of the silicon nitride film 3a that is located above the silicon oxide film 2, thereby leaving the silicon nitride film 3 in the recess 30. Herein, the silicon nitride film 3 does not need to be in contact with the glass substrate 1. Specifically, a portion of the silicon oxide film 2 may remain between the silicon nitride film 3 and the glass substrate 1, or any other film may be present. The silicon nitride film 3 has a higher thermal conductivity than that of the silicon oxide film 2. In the present embodiment, any other insulating film having a higher thermal conductivity than that of the silicon oxide film 2 may be formed instead of the silicon nitride film 3.

Next, as shown in FIG. 3(d), a plasma CVD technique is performed by using Si₂H₆ gas and H₂ gas, thereby forming an amorphous silicon film 4 which is in contact with the upper face of the silicon oxide film 2 and the silicon nitride film 3, the amorphous silicon film 4 having a thickness of 50 nm.

Next, as shown in FIG. 3(e), the amorphous silicon film 4 is irradiated with pulsed excimer laser light 5. As this pulsed excimer laser light 5, laser light whose energy as obtained by dividing the output energy per pulse by the irradiated area (hereinafter referred to as pulse energy density) is 380 mJ/cm² is used. As the pulsed excimer laser, it is preferable to radiate XeCl (wavelength 308 nm, pulse width 60 nsec, pulse interval 4 msec, frequency 250 Hz).

Since the thermal conductivity of the silicon nitride film 3 is greater than the thermal conductivity of the silicon oxide film 2, the heat which is generated in the amorphous silicon film 4 due to irradiation of the pulsed excimer laser light 5 is more likely to be released in the silicon nitride film 3 than in the silicon oxide film 2. Therefore, as shown in FIG. 3(f), at the portion of the amorphous silicon film 4 that is located above the silicon nitride film 3, the temperature is not sufficiently increased for the amorphous silicon film 4 to be melted, and therefore crystallization does not progress. As a result, the amorphous state is conserved, whereby the amorphous silicon film 6 is obtained. On the other hand, at the portion of the amorphous silicon film 4 that is located above the silicon oxide film 2, heat is retained so that temperature is sufficiently increased. As a result, the amorphous silicon film 4 is melted, thus allowing crystallization to progress. As a result, the crystalline silicon film 7, which has an average grain size of e.g. 200 nm or less, is formed.

Thus, according to the present embodiment, the layout of the crystalline silicon film 7 and the amorphous silicon film 6 can be determined based on the layout of the silicon oxide film 2 and the silicon nitride film 3, and thus the crystalline silicon film 7 and the amorphous silicon film can be freely disposed in regions close to each other. Therefore, by using the multilayer film of the present embodiment, a TFT which is required to have high carrier-mobility characteristics can be formed by using the crystalline silicon film 7, and a TFT having little leak current can be formed by using the amorphous silicon film 6.

### Embodiment 2

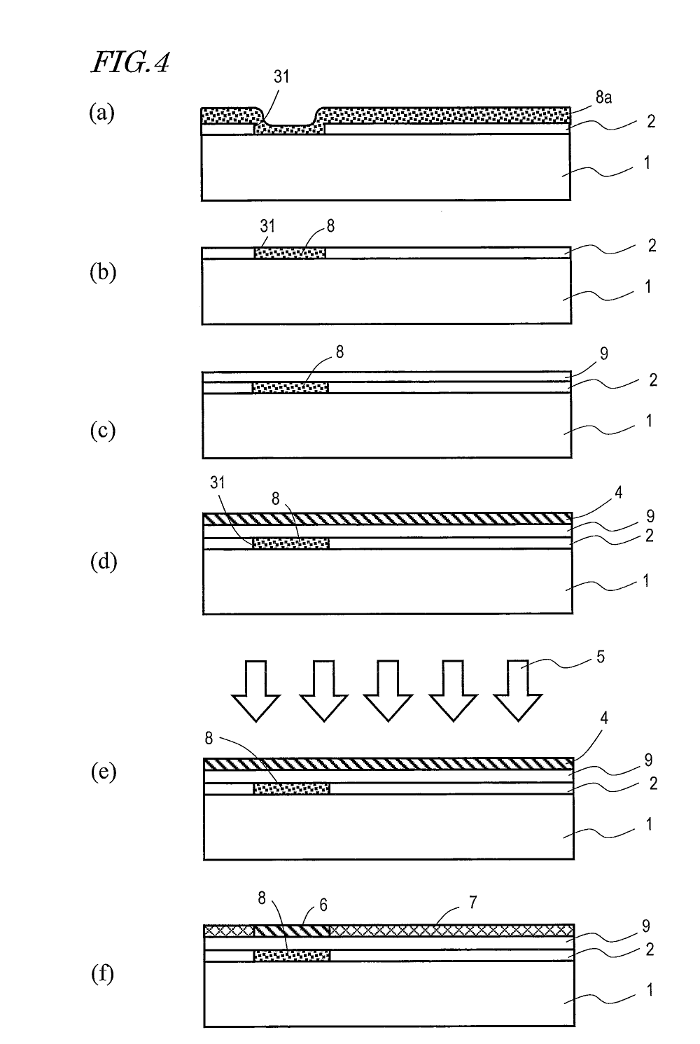

Hereinafter, a production method for a multilayer film of Embodiment 2 will be described with reference to FIGS. 4(a) to (f). FIGS. 4(a) to (f) are schematic diagrams showing steps of producing the multilayer film of Embodiment 2.

In the production method for the multilayer film of the present embodiment, as shown in FIG. 4(a), first, a plasma CVD (chemical vapor deposition) technique is performed by using TEOS (tetraethoxysilane) gas and O₃ gas, thereby forming on the glass substrate 1 the silicon oxide film 2 having a thickness of 200 nm. Herein, the silicon oxide film 2 does not need to be in contact with the glass substrate 1, but only needs to be supported by the glass substrate 1.

Thereafter, an RIE (reactive ion etching) technique is performed by using CF₄ gas and CHF₃ gas to remove a portion of the silicon oxide film 2 until the glass substrate is exposed, thereby forming a recess 31. Next, a sputtering technique is performed to form a W film 8a having a thickness of 200 nm. Herein, the W film 8a covers the silicon oxide film 2 and the glass substrate 1 exposed in the recess 31.

Next, as shown in FIG. 4(b), an RIE technique is performed by using CF₄ gas and Cl₂ gas to remove a portion of the W film 8a that is located above the silicon oxide film 2, thereby leaving a W film 8 in the recess 31. Herein, the W film 8 does not need to be in contact with the glass substrate 1, but only needs to be supported by the glass substrate 1. Generally speaking, the W film 8 has a higher thermal conductivity than that of the silicon oxide film 2. In the present embodiment, a conductor film having a higher thermal conductivity than that of the silicon oxide film 2 may be formed instead of the W film 8.

Next, as shown in FIG. 4(c), a plasma CVD technique is performed by using TEOS gas and O₃ gas, thereby forming a silicon oxide film 9 on the silicon oxide film 2 and the W film 8, the silicon oxide film 9 having a thickness of 200 nm.

Then, as shown in FIG. 4(d), a plasma CVD technique is performed by using Si₂H₆ gas and H₂ gas, thereby forming on the silicon oxide film 9 the amorphous silicon film 4 having a thickness of 50 nm.

Next, as shown in FIG. 4(e), under conditions similar to those of Embodiment 1, the amorphous silicon film 4 is irradiated with pulsed excimer laser light 5 having a pulse energy density of 380 mJ/cm². Upon radiation of the pulsed excimer laser light 5, heat is generated in the amorphous silicon film 4, and this heat propagates to the silicon oxide film 9. Since the thermal conductivity of the W film 8 is greater than the thermal conductivity of the silicon oxide film 2, the heat having propagated to the silicon oxide film 9 is more likely to be released in the W film 8 than in the silicon oxide film 2. Therefore, as shown in FIG. 4(f), at the portion of the amorphous silicon film 4 that is located above the W film 8, the temperature is not sufficiently increased for melting of the amorphous silicon film 4 to progress, and therefore crystallization does not progress. As a result, the amorphous state is conserved, whereby the amorphous silicon film 6 is obtained. On the other hand, at the portion of the amorphous silicon film 4 that is located above the silicon oxide film 2, sufficient heat is retained so that the temperature is increased. As a result, melting of the amorphous silicon film 4 progresses, and crystallization progresses, whereby the crystalline silicon film 7 is formed.

Thus, according to the present embodiment, the crystalline silicon film 7 and the amorphous silicon film 6 can be freely disposed in regions close to each other. Therefore, by using the multilayer film of the present embodiment, a TFT which is required to have high carrier-mobility characteristics can be formed by using the crystalline silicon film 7, and a TFT which is required to have low leak-current characteristics can be formed by using the amorphous silicon film 6.

### Embodiment 3

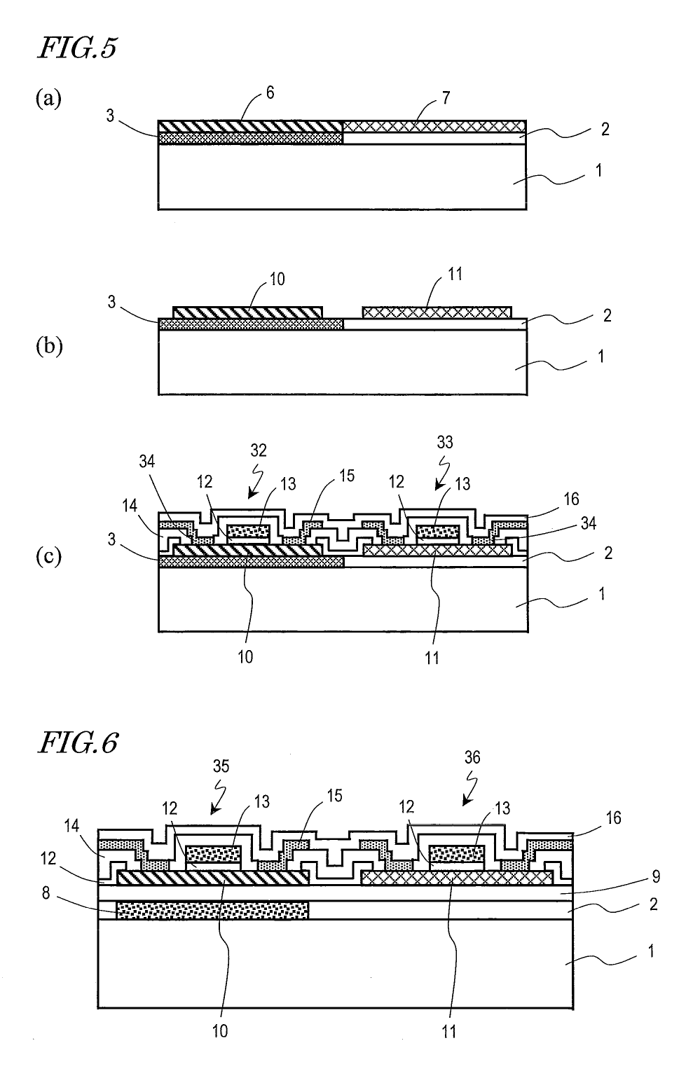

Next, the structure of a semiconductor device in which the multilayer film of Embodiment 1 is used will be described with reference to FIG. 5(c). FIGS. 5(a) to (c) are schematic diagrams showing a production method for the semiconductor device of Embodiment 3, where FIG. 5(c) shows a completed state of the semiconductor device of Embodiment 3.

As shown in FIG. 5(c), in the semiconductor device of the present embodiment, TFTs 32 and 33 are provided for each pixel of the display device. Moreover, the semiconductor device of the present embodiment includes: a substrate 1; a silicon nitride film 3 formed on a portion of the substrate 1; and a silicon oxide film 2 formed on another portion of the substrate 1. The silicon oxide film 2 has a lower thermal conductivity than that of the silicon nitride film 3. An amorphous silicon layer 10 is formed on the silicon nitride film 3, and a crystalline silicon layer 11 is formed on the silicon oxide film 2. The amorphous silicon layer 10 composes the TFT 32, whereas the crystalline silicon layer 11 composes the TFT 33.

On the amorphous silicon layer 10 and the crystalline silicon layer 11, respectively, a silicon oxide film 12 functioning as a gate insulating film and a W film 13 functioning as a gate electrode are formed. Although omitted from illustration, a source region and a drain region are formed in the amorphous silicon layer 10. Similarly, a source region and a drain region are formed in the crystalline silicon layer 11.

The W film 13, the amorphous silicon layer 10, and the crystalline silicon layer 11 are covered by a silicon oxide film 14. In the silicon oxide film 14, contact holes for exposing the amorphous silicon layer 10 and the crystalline silicon layer 11 are formed. Al wiring 15 is formed from within the contact holes 34 to over the surrounding silicon oxide film 14, and a silicon nitride film 16 is formed on the Al wiring 15 and the silicon oxide film 14.

Next, a production method for the semiconductor device of the present embodiment will be described with reference to FIGS. 5(a) to (c).

According to the production method of the present embodiment, as shown in FIG. 5(a), first, a substrate having the amorphous silicon film 6 and the crystalline silicon film 7 formed on its surface is provided. Then, as shown in FIG. 5(b), a patterning is performed by an RIE technique using CF₄ gas and O₂ gas, thereby forming an island-shaped amorphous silicon layer 10 and an island-shaped crystalline silicon layer 11.

Next, a step for forming the TFTs 32 and 33 as shown in FIG. 5(c) is performed. First, a plasma CVD technique is performed by using TEOS gas and O₃ gas to form the silicon oxide film 12 functioning as a gate insulating film on each of the island-shaped amorphous silicon layer 10 and the crystalline silicon layer 11. Furthermore, a sputtering technique is performed to form a W film (not shown) on the silicon oxide film 12, and an RIE technique is performed by using CF₄ gas and Cl₂ gas to form the W film 13, which functions as a gate electrode. Next, an ion implantation with P or B is performed for the amorphous silicon layer 10 and the crystalline silicon layer 11, thereby forming a source region (not shown) and a drain region (not shown) in the amorphous silicon layer 10. Similarly, a source region (not shown) and a drain region (not shown) are also formed in the crystalline silicon layer 11.

Next, a plasma CVD technique is performed by using TEOS gas and O₃ gas to form the silicon oxide film 14 covering the amorphous silicon layer 10 and the crystalline silicon layer 11 as well as the W film 13 formed thereupon. Thereafter, an RIE technique is performed by using CF₄ gas and CHF₃ gas to form the contact holes 34, the contact holes 34 penetrating through the silicon oxide film 14 so as to expose the amorphous silicon layer 10 and the crystalline silicon layer 11. Then, a sputtering technique is performed to form an Al film (not shown) which extends from within the contact holes 34 over to the silicon oxide film 14. Thereafter, an RIE technique is performed by using BCl₃ gas and Cl₂ gas to remove unnecessary portions of the Al film, thus forming the Al wiring 15. The portions of the Al wiring 15 that are located in the contact holes 34 each function as a source electrode or a drain electrode. Thereafter, a plasma CVD technique is performed by using SiH₄ gas, NH₃ gas, and N₂ gas to form the silicon nitride film 16 on the Al wiring 15 and the silicon oxide film 14. Through the above steps, the TFTs 32 and 33 are formed.

In the present embodiment, the TFTs 32 and 33 can be formed by using the amorphous silicon layer 10 and the crystalline silicon layer 11, respectively. Therefore, the leak current can be reduced in the TFT 32, whereas a high carrier mobility can be realized in the TFT 33.

The method of the present embodiment is particularly useful in the case where a TFT for applying a voltage across the liquid crystal and a TFT for composing an SRAM circuit are formed for each pixel, as disclosed in Patent Document 2. That is, by using the TFT 32 having the amorphous silicon layer 10 as a TFT for applying a voltage across the liquid crystal, and using the TFT 33 having the crystalline silicon layer 11 as a TFT composing an SRAM, the leak current can be reduced in the TFT for applying a voltage across the liquid crystal and a high carrier mobility can be realized in the TFT composing an SRAM. Note that the TFT having a high carrier mobility will be useful not only as a TFT composing an SRAM, but also in peripheral circuitry.

### Embodiment 4

Hereinafter, a semiconductor device in which the multilayer film of Embodiment 2 is used will be described.

FIG. 6 is a schematic diagram showing the semiconductor device of Embodiment 4.

In the semiconductor device of Embodiment 4, as shown in FIG. 6, a silicon oxide film 2 and a W film 8 having a higher thermal conductivity than that of the silicon oxide film 2 are each supported on the substrate 1. The silicon oxide film 2 and the W film 8 are covered by a silicon oxide film 9. The portion of the silicon oxide film 9 that is located above the silicon oxide film 2 is covered by the crystalline silicon layer 11, whereas the portion of the silicon oxide film 9 that is located above the W film 8 is covered by the amorphous silicon layer 10. The crystalline silicon layer 11 composes a TFT 36, whereas the amorphous silicon layer 10 composes a TFT 35. Note that the present embodiment is similar in constitution to the third embodiment, except for using the multilayer film of Embodiment 2 instead of the multilayer film of Embodiment 1. Therefore, the descriptions of the TFTs 35 and 36, and the like will be omitted.

The W film 8, which is present between the glass substrate 1 and the amorphous silicon layer 10, is connected to the W film 13 or the Al wiring 15 through contact holes (omitted from illustration). The W film 8 may be connected to any arbitrary potential such as the ground potential, or may be used as an electrode for controlling the threshold value voltage of a TFT. Moreover, together with the W film 13, the W film 8 may be used as a gate electrode of the TFT 35. In this case, the W film 8 will become a gate electrode on the rear face side.

In the present embodiment, effects similar to those of Embodiment 3 are obtained, the descriptions of which are omitted.

### Embodiment 5

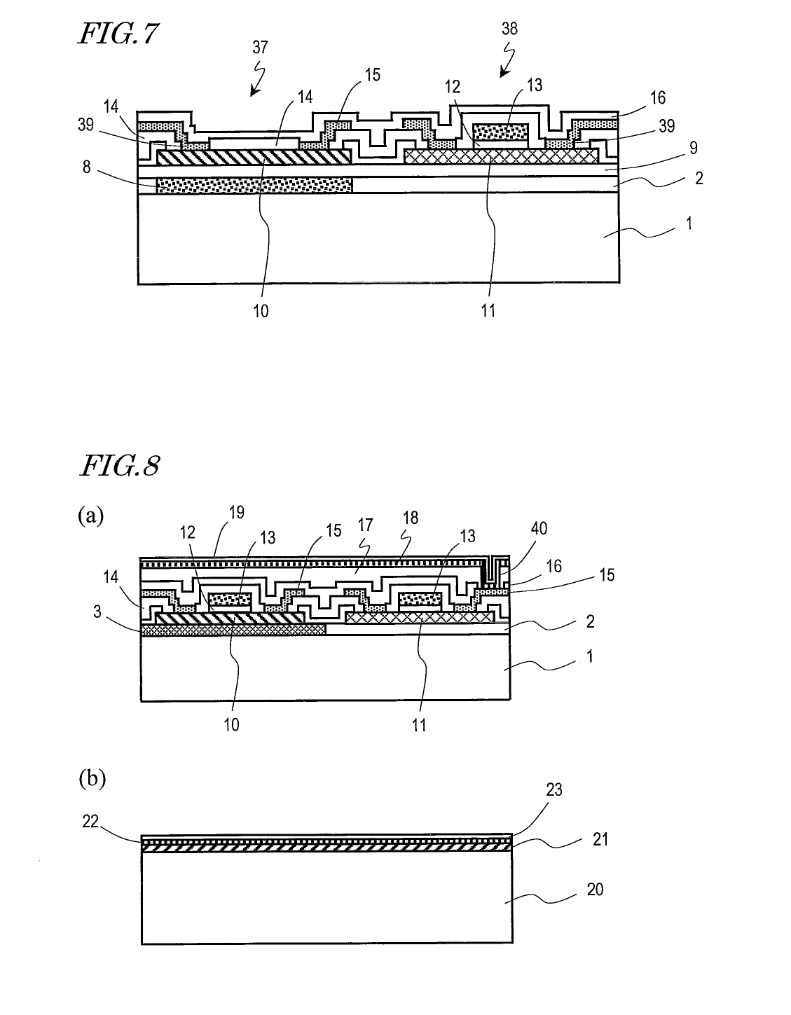

Hereinafter, a semiconductor device in which the W film 8 in the multilayer film of Embodiment 2 is used as a gate electrode will be described. FIG. 7 is a schematic diagram showing the semiconductor device of Embodiment 5.

As shown in FIG. 7, in the semiconductor device of the present embodiment, the W film 8 is used as a gate electrode of the TFT 37. The silicon oxide film 9 that is located above the W film 8 functions as a gate insulating film, whereas the amorphous silicon layer 10, which is located above the silicon oxide film 9, functions as an active region. Although omitted from illustration, a source region and a drain region are formed in the amorphous silicon layer 10.

In the semiconductor device of the present embodiment, since the W film 8 functions as a gate electrode, the silicon oxide film 12 and the W film 13 as described in Embodiments 3 and 4 (shown in FIGS. 5 and 6) are not formed. In other words, the silicon oxide film 14 is in contact with the amorphous silicon layer 10 from above the amorphous silicon layer 10. Contact holes 39 for exposing the amorphous silicon layer 10 are formed in the silicon oxide film 14, and Al wiring 15 is formed from the contact holes 39 to over the surrounding silicon oxide film 14. A silicon nitride film 16 is formed on the silicon oxide film 14 and the Al wiring 15. Although not appearing in the cross section shown in FIG. 7, a wiring line is in contact with the W film 8, so that a gate voltage is applied to the W film 8 through this wiring line. The other constitution is similar to that of the fourth embodiment, and the descriptions thereof are omitted.

Note that, in order to obtain the semiconductor device of the present embodiment, the production method of Embodiment 3 may be changed as follows, for example. With the silicon oxide film 12 and the W film 13 (shown in FIG. 5) formed also on the amorphous silicon layer 10, an ion implantation for forming source regions and drain regions is performed. Thereafter, the silicon oxide film 12 and the W film 13 that are located above the amorphous silicon layer 10 are removed, and the silicon oxide film 14 is formed. In this manner, a source region and a drain region can also be formed in the amorphous silicon layer 10.

According to the present embodiment, effects similar to those of Embodiment 3 are obtained.

### Embodiment 6

Hereinafter, a liquid crystal display device in which the semiconductor device of Embodiment 3 is used will be described. FIG. 8(a) is a schematic diagram showing the structure of a TFT substrate in the liquid crystal display device of Embodiment 6, whereas FIG. 8(b) is a schematic diagram showing the structure of a CF substrate in the liquid crystal display device of Embodiment 6.

As shown in FIG. 8(a), in the TFT substrate of the present embodiment, a resin film 17, an ITO film 18, and a polyimide film 19 are formed on the semiconductor device of Embodiment 3. Specifically, the resin film 17 is formed on the silicon nitride film 16, such that the resin film 17 buries the bumps and dents on the surface of the silicon nitride film 16. A contact hole 40 reaching the Al wiring 15 is formed in the resin film 17, and the resin film 17 and the surface of the contact hole 40 are covered by the ITO film 18. The ITO film 18 is in contact with the Al wiring 15 within the contact hole 40. The upper face of the ITO film 18 is covered by a polyimide film 19, which is an alignment film.

On the other hand, in the CF substrate of the present embodiment, as shown in FIG. 8(b), a color filter 21 of R (red), G (green), and B (blue) is formed on a glass substrate 20. On the color filter 21, an ITO film 22 which is a counter electrode and a polyimide film 23 which is an alignment film are formed in this order.

Although omitted from illustration, in the liquid crystal display device of the present embodiment, the TFT substrate and the CF substrate are placed so as to oppose each other. The space bet the TFT substrate and the CF substrate is filled with liquid crystal which serves as a display medium.

Next, a production method for the liquid crystal display device of the present embodiment will be described by referring back to FIGS. 8(a) and (b).

In the production method of the present embodiment, in order to form the TFT substrate shown in FIG. 8(a), formation up to the silicon nitride film 16 is performed according to the method of Embodiment 3, and thereafter a resin film 17 is formed over the entire silicon nitride film 16. Next, a patterning is performed through a photolithography step and etching to form the contact hole 40 reaching the Al film 15. Thereafter, after forming the ITO film 18 covering the upper face of the resin film 17 and the interior of the contact hole 40 by sputtering technique, a photolithography step and an etching using HCl and FeCl₃ are performed to pattern the ITO film 18. Thereafter, an offset printing technique is performed to form the polyimide film 19 on the ITO film 18, and a rubbing treatment is performed.

On the other hand, in order to form the CF substrate shown in FIG. 8(b), a glass substrate 20 is provided, apart from the glass substrate 1 shown in FIG. 8(a). Then, a film to which respective photosensitive resin films of R, G, B are added is transferred onto the glass substrate 20 via thermocompression, and thereafter the film is patterned through a photolithography step and etching. Furthermore, at the boundaries of the R, G, and B photosensitive resin films, a black matrix portion having light blocking ability is formed, thus producing the color filter 21. Thereafter, a sputtering technique is performed to form the ITO film 22 over the entire upper face of the color filter 21. Furthermore, an offset printing technique is performed to form on the ITO film 22 the polyimide film 23, which is an alignment film, and a rubbing treatment is performed.

The TFT substrate and CF substrate thus formed are placed so that their faces that have been subjected to a rubbing treatment oppose each other, and are attached together by using seal resin. At this time, silica in spherical or cylindrical form is scattered between the glass substrates 1 and 20 so as to maintain a constant spacing between the glass substrates 1 and 20. Then, after sealing the liquid crystal to serve as a display medium in between the glass substrates 1 and 20, polarizers and the like are attached on the outside of the glass substrates 1 and 20, whereby the liquid crystal display is completed.

Although the present embodiment is directed to a liquid crystal display device in which the semiconductor device of Embodiment 3, the semiconductor device of Embodiment 4 or Embodiment 5 may also be used instead.

### Other Embodiments

According to the production methods of Embodiments 1 and 2, the amorphous silicon film 4 is irradiated with pulsed excimer laser light 5. However, continuous-wave laser light may be used instead of pulsed laser light. Excimer laser light is suitable for the present invention in that it is absorbed by a silicon film of a predetermined film thickness, and that it does not result in significantly different absorption coefficients between amorphous silicon and crystalline silicon. However, laser light other than excimer laser light may be used. Moreover, instead of laser light, non-coherent light may be used. Moreover, an energy beam may be used instead of light, e.g., an electron beam. In the case of using an electron beam, in order to facilitate its absorption by silicon, an acceleration voltage of 10 kV or less is preferably used.

In the production methods of Embodiments 1 and 2, amorphous silicon is used as an amorphous semiconductor film. However, other semiconductor materials may be used, e.g., Ge or SiGe.

In Embodiment 3, a silicon oxide film as a gate insulating film is simultaneously formed on the amorphous silicon layer 10 and on the crystalline silicon layer 11 to result in the same film thickness. However, the silicon oxide film may be separately formed with different film thicknesses. Other insulating films may also be used, e.g., a silicon nitride film.

In the production methods of Embodiments 1 and 2, the amorphous silicon layer 10 is formed directly on the silicon oxide film 2 and the silicon nitride film 3. However, a silicon oxide film or the like may be present between the silicon oxide film 2 and silicon nitride film 3 and the amorphous silicon layer 10.

In the production methods of Embodiments 1 and 2, a multilayer film is formed by using the glass substrate 1. However, a substrate which does not transmit visible light may be used in the present invention.

Other than the liquid crystal display device of Embodiment 6, the present invention is also applicable to other displays, e.g., an EL (Electro Luminescence) display.

In order to prevent an unexpected current from flowing due to light striking the TFTs, the W film 8 in the production method of Embodiment 2 may be utilized as a light-shielding film. Moreover, any material other than a W film that blocks visible light may be used as a light-shielding film. This light-shielding film can prevent light entering from the outside toward the interior of the liquid crystal from reaching the TFTs.

Although Embodiment 3 is directed to a semiconductor device in which an SRAM is formed for each pixel, the present invention is also applicable to a semiconductor device in which a DRAM is formed for each pixel. The present invention is also applicable to a semiconductor device in which a TFT having little leak current and being formed by using an amorphous semiconductor layer is provided for each pixel and a TFT having a high carrier mobility and being formed by using a crystalline semiconductor layer is provided in peripheral circuitry or the like outside the pixels.

### INDUSTRIAL APPLICABILITY

The present invention is applicable to a production method for a multilayer film, a production method for a semiconductor device, and a semiconductor device and a display device.

1. A production method for a multilayer film, comprising:
step (a) of forming a first film supported by a substrate;
step (b) of forming a second film being supported by the substrate and having a lower thermal conductivity than that of the first film;
step (c) of depositing a semiconductor film in an amorphous state above the first film and the second film; and
step (d) of irradiating portions of the semiconductor film that are located above the first film and the second film with an energy beam of a same intensity, thereby crystallizing the portion of the semiconductor film that is located above the second film and leaving the portion of the semiconductor film that is located above the first film in the amorphous state.

2. The production method for a multilayer film of claim 1, wherein in step (c), the semiconductor film is formed so as to be in direct contact with the first film and the second film.

3. The production method for a multilayer film of claim 1, further comprising, after step (b) and before step (c), a step of forming a third film which is in direct contact with the first film and the second film, wherein,
in step (c), the semiconductor film is formed on the third film.

4. The production method for a multilayer film of claim 1, wherein the first film is an insulating film.

5. The production method for a multilayer film of claim 1, wherein the first film is an electrically conductive film.

6. The production method for a multilayer film of claim 1, wherein the energy beam is light.

7. The production method for a multilayer film of claim 6, wherein the light is laser light.

8. The production method for a multilayer film of claim 1, wherein the semiconductor film contains at least one of silicon and germanium.

9. A production method for a semiconductor device, comprising:
step (a) of forming a first film supported by a substrate;
step (b) of forming a second film being supported by the substrate and having a lower thermal conductivity than that of the first film;
step (c) of depositing a semiconductor film in an amorphous state above the first film and the second film; and
step (d) of irradiating portions of the semiconductor film that are located above the first film and the second film with an energy beam of a same intensity, thereby crystallizing the portion of the semiconductor film that is located above the second film to form a crystalline semiconductor film and leaving the portion of the semiconductor film that is located above the first film in the amorphous state to become an amorphous semiconductor film.

10. The production method for a semiconductor device of claim 9, further comprising, after step (d),
step (e) of performing a patterning to form an island-shaped crystalline semiconductor layer which at least includes a portion of the crystalline semiconductor film and an island-shaped amorphous semiconductor layer which at least includes a portion of the amorphous semiconductor film, and
step (f) of forming thin film transistors by respectively using the island-shaped crystalline semiconductor layer and the island-shaped amorphous semiconductor layer.

11. A semiconductor device having a first thin film transistor and a second thin film transistor, comprising:
a substrate;
a first film supported by the substrate;
a second film being supported by the substrate and having a lower thermal conductivity than that of the first film;
an amorphous semiconductor layer formed above the first film, the amorphous semiconductor layer composing the first thin film transistor; and
a crystalline semiconductor layer fowled above the second film, the crystalline semiconductor layer composing the second thin film transistor.

12. The semiconductor device of claim 11, wherein the first thin film transistor and the second thin film transistor are provided for each pixel.

13. The semiconductor device of claim 11, wherein the first thin film transistor is provided for each pixel, and the second thin film transistor is provided outside the pixels.

14. The semiconductor device of claim 11, wherein,
the amorphous semiconductor layer is in direct contact with the first film; and
the crystalline semiconductor layer is in direct contact with the second film.

15. The semiconductor device of claim 11, wherein,
a third film is formed on the first film and the second film; and
the amorphous semiconductor layer and the crystalline semiconductor layer are formed on the third film.

16. The semiconductor device of claim 11, wherein the first film is an electrode which is connected to an arbitrary potential, including a ground potential.

17. The semiconductor device of claim 11, wherein the first film is an electrode for controlling a threshold value voltage of the first thin film transistor.

18. The semiconductor device of claim 11, wherein the first film is a gate electrode of the first thin film transistor.

19. The semiconductor device of claim 11, wherein the substrate is made of a material which transmits visible light.

20. The semiconductor device of claim 11, wherein the first film is made of a material which blocks visible light.

21. A display device comprising the semiconductor device of claim 11.
